(19) United States
(12) Patent Application Publication
(10) Pub. No.: US 2025/0197678 A1
(43) Pub. Date: Jun. 19, 2025

(54) LONG FILM AND METHOD FOR MANUFACTURING CONNECTION STRUCTURE

(71) Applicant: DEXERIALS CORPORATION, Shimotsuke-shi, Tochigi (JP)

(72) Inventors: Yusuke TANAKA, Tochigi (JP); Shogo TAMAGAWA, Tochigi (JP)

(73) Assignee: DEXERIALS CORPORATION, Shimotsuke-shi, Tochigi (JP)

(21) Appl. No.: 18/845,324

(22) PCT Filed: Mar. 17, 2023
(86) PCT No.: PCT/JP2023/010732

§ 371 Date: Sep. 9, 2024

(30) Foreign Application Priority Data
Mar. 31, 2022 (JP) 2022-061427

(51) Int. Cl. C09J 7/00; B41M 5/26; C09J 5/00

(52) U.S. Cl. CPC C09J 7/00; B41M 5/26; C09J 5/00; C09J 2203/326; C09J 2301/204; C09J 2301/416

(57) ABSTRACT

A long film capable of maintaining the performance of individualized pieces of adhesive film and a method for manufacturing a connection structure. A long film has a long base material film and individualized pieces of adhesive film arranged in the longitudinal direction of the base material film, and an identification mark is provided on at least one of the predetermined individualized pieces or the base material film on which the predetermined individualized pieces are arranged. This allows defective individualized pieces to be avoided by identifying the identification mark when the individualized pieces are used, thereby maintaining the performance of the adhesive film individualized pieces.

### TECHNICAL FIELD

This technology relates to a long film in which individualized pieces are arranged in the longitudinal direction of a base material film and a method for manufacturing a connection structure. This application claims priority based on Japanese Patent Application No. 2022-061427 filed in Japan on Mar. 31, 2022, which is hereby incorporated by reference into this application.

### BACKGROUND ART

Recently, adhesive films such as anisotropic conductive film (ACF), conductive film, and adhesive film (non-conductive film: NCF) are punched into individualized pieces of a desired shape, and a long film in which the individualized pieces arranged in the longitudinal direction on a base material film is wound onto a reel for shipping (e.g., see Patent Document 1).

However, during the punching process, e.g., debris may remain, debris may adhere to the individualized pieces, or individualized pieces may turn up, so that it is necessary to inspect and pick up defective individualized pieces from each individualized piece of the long film.

The picking up of the defective individualized pieces, which is carried out after the inspection, may affect the individualized pieces at both ends of the defective individualized pieces. In addition, a debris of the adhesive film may remain on the base material film and become a foreign object in the production line for the connection structure. As a result, it is difficult to maintain the performance of individualized pieces of a long film in such a pick-up of defective individualized pieces.

### CITATION LIST

### Patent Literature

Patent Document 1: JP 2020-198422 A

### SUMMARY OF INVENTION

### Technical Problem

This technology is proposed in view of such existing circumstances and provides a long film capable of maintaining the performance of individualized pieces of adhesive film and a method for manufacturing a connection structure.

### Solution to Problem

The long film of the present technology includes a long base material film and individualized pieces of adhesive film arranged in the longitudinal direction of the base material film, and at least one of a predetermined individualized piece or the base material film on which the predetermined individualized piece is arranged is provided with an identification mark.

### Advantageous Effects of Invention

According to this technology, when using the individualized pieces, defective individualized pieces can be avoided by image recognition of the identification mark to ensure the performance of the individualized pieces of adhesive film.

### BRIEF DESCRIPTION OF DRAWINGS

FIG. 1 illustrates an example of a long film.

FIG. 2 is a schematic diagram showing an example of defective individualized pieces having a window frame, wherein FIG. 2A shows a state in which foreign matter has been mixed in, FIG. 2B shows a state in which distortion has occurred, and FIG. 2C shows a state in which chipping has occurred.

FIG. 3 illustrates examples of the identification mark.

FIG. 4 illustrates an example of an inspection marking device.

FIG. 5 illustrates an explanatory view of the operation of a detection sensor, wherein FIG. 5A shows the detection sensor that detects each individualized piece of long film conveyed, and FIG. 5B shows the detection signal of the individualized pieces detected by the detection sensor.

FIG. 6 illustrates an explanatory view of the detection timing of the detection sensor.

FIG. 7 illustrates an explanatory view of defect-detection and non-defect-detection signals in the inspection judgment.

FIG. 8 illustrates an example of identification marks provided by a laser marker.

FIG. 9 illustrates an example of acceleration and deceleration waveforms of a long film supply motor or a collection motor.

FIG. 10 is a flowchart showing an inspection method for a long film.

### DESCRIPTION OF EMBODIMENTS

Embodiments of the present disclosure will now be more particularly described according to the following order with reference to the accompanying drawings.
1. LONG FILM
2. INSPECTION MARKING DEVICE
3. METHOD FOR MANUFACTURING LONG FILM
4. METHOD FOR MANUFACTURING CONNECTING STRUCTURE

### 1. Long Film

The long film according to the present embodiment includes a long base material film and individualized pieces of adhesive film arranged in the longitudinal direction of the base material film, and at least one of the predetermined individualized pieces or the base material film on which the predetermined individualized pieces are arranged is provided with an identification mark to enable a defective individualized piece to be identified. This makes it possible to avoid defective individualized pieces by identifying the identification mark, e.g., by image recognition, when the individualized pieces are used, to ensure the performance of the individualized pieces of adhesive film.

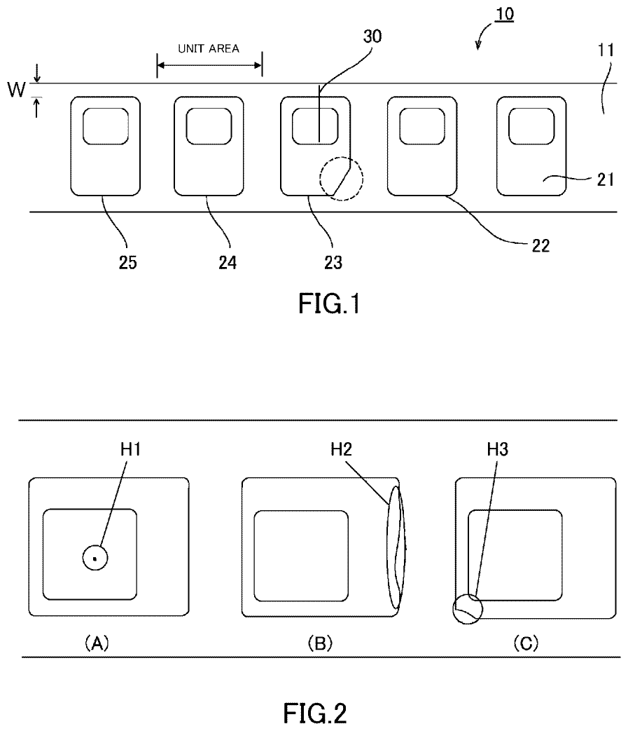

FIG. 1 illustrates an example of a long film. As shown in FIG. 1, the long film 10 includes a long base material film 11 and individualized pieces 21 to 25 of adhesive film arranged in the longitudinal direction of the base material film 11, and an individualized piece 23 that is a defective individualized piece and the base material film 11 on which the defective individualized piece 23 is arranged is provided with an identification mark 30.

The long film 10 preferably has an edge area consisting of the base material film 11 at the edge in the width direction. The length W in the width direction of the edge area consisting of the base material film 11 is preferably 100 μm or more, more preferably 500 μm or more, and still more preferably 1,000 μm or more. This allows an identification mark to be applied to the edge area consisting of the base material film 11, thereby reducing the deterioration of the print quality compared to the case where the identification mark is applied to individualized pieces. In addition, the presence of such an edge area makes it difficult for adhesive to protrude from the film, which tends to occur when the film is long. This is because it is difficult for the adhesive to reach the edge of the base material film, thus preventing so-called blocking, which improves practical convenience. As described below, blocking is less likely to occur when the individualized piece is far from the edge of the base material film, which also contributes to productivity.

The long film 10 may have the individualized pieces 21 to 25 arranged continuously in unit areas in the longitudinal direction and may be wound on a reel. Here, the “unit area” is an area having, e.g., a rectangular shape with a predetermined length in the longitudinal direction of the base material and can be considered as an area defined by the centerline between two adjacent individualized pieces and the next centerline between next two adjacent individualized pieces, or an area including one individualized piece sandwiched between the centerlines between the adjacent individualized pieces. The adhesive film can be peeled off and separated from the base material film. In this technology, the adhesive film of the individualized piece has no corresponding support and consists only of a layer of adhesive (although a cover film of approximately the same width as the base material may be laminated thereto).

The base material film 11 is a support film that supports multiple individualized pieces. The base material film 11 may be made of, e.g., polyethyleneterephthalate (PET), oriented polypropylene (OPP), poly-4-methylpentene-1 (PMP), and polytetrafluoroethylene (PTFE), among others. Further, a material in which at least the side of the individualized pieces is release treated with silicone resin can be suitably used as the base material film 11.

The thickness of the base material film 11 is not particularly limited. The lower limit of the thickness of the base material film 11 is preferably 10 μm or more, more preferably 25 μm or more, and still more preferably 38 μm or more from the viewpoint of releasing. The upper limit of the thickness of the base material film is preferably 200 μm or less, more preferably 100 μm or less, still more preferably 75 μm or less, and may be 50 μm or less, because there is concern that excessive pressure may be applied to the adhesive film if too thick. When a cover film is provided on an individualized piece of the adhesive film, the thickness of the cover film will be in the same range, but the cover film is preferably thinner than the base material film.

The width of the base material film 11 is also not limited. The lower limit of the width of the base material film 11 is preferably 1 mm or more, more preferably 2 mm or more, and still more preferably 4 mm or more from the viewpoint of winding. The upper limit of the width of the base material film 11 is preferably 500 mm or less, more preferably 250 mm or less, and still more preferably 120 mm or less because of the concern that too large a width may make carrying and handling difficult.

Adhesive films are not limited and may include anisotropic conductive film (ACF), conductive film with conductive particles contained in the adhesive, adhesive film (non-conductive film: NFC), and solder-containing film with solder particles, among others. The binder of the adhesive film can be thermosetting or thermoplastic.

When containing conductive particles such as metal particles, resin core metal-coated particles, and solder particles, the individualized pieces may have areas that contain conductive particles and areas that do not contain conductive particles. The individualized pieces may be composed of two or more layers, two or more laminated layers composed of layers containing conductive particles or solder particles and layers not containing conductive particles, two or more mutually laminated layers composed of layers containing conductive particles, or two or more mutually laminated layers composed of layers not containing conductive particles.

The individualized pieces of adhesive film are not limited in shape and may have a rectangular U-shape with two horizontal sides and one vertical side, a square shape with two horizontal sides and two vertical sides, L-shape, U-shape, and C-shape, among others, as described, e.g., in JP 2020-198422 A. When containing conductive particles, the conductive particles may be embedded in insulating resin, as described in Japanese Patent No. 6187665. The conductive particles may be randomly or regularly arranged, and the conductive particles are preferably aligned in the film thickness direction. When containing solder particles, as described in Japanese Patent No. 6898413, a thermoplastic resin, which is solid at room temperature and has a melt flow rate of 10 g/10 min or higher when measured at a temperature of 190° C. and a load of 2.16 kg, is preferably blended to achieve a thickness of 50% to 300% of the average particle of the solder particles, and as described in Japanese Patent No. 7032367, the minimum melt viscosity of the adhesive film is preferably less than 100 Pa*s. The binder of the adhesive film can be thermosetting or thermoplastic. It may be a single layer or laminated in multiple layers.

The thickness of the individualized pieces is not particularly limited, and the lower limit of the thickness of the individualized pieces is preferably 1 μm or more, more preferably 3 μm or more, still more preferably 4 μm or more, and the upper limit of the thickness of the individualized pieces is preferably 50 μm or less, more preferably 20 μm or less, still more preferably 10 μm or less.

The thickness of the individualized pieces can be measured using a known micrometer or digital thickness gauge (e.g., 0.0001 mm minimum indication). However, if the thickness of the individualized pieces is thinner than the particle diameter of the conductive particles, a contact-type thickness gauge is not suitable, so a laser displacement gauge (e.g., spectral interference displacement type) is preferred. Here, the thickness of an individualized piece is the thickness of the binder resin layer only and does not include the particle diameter of the conductive particles.

As shown in FIG. 1, the individualized piece may have a window frame in which the base material film 11 is exposed, and an identification mark 30 may be provided on the base material film of the window frame. This technology is especially useful for individualized pieces having window frames because they can be easily damaged to become defective individualized pieces.

FIG. 2 is a schematic diagram showing an example of defective individualized pieces having a window frame, wherein FIG. 2A shows a state in which foreign matter has been mixed in, FIG. 2B shows a state in which distortion has occurred, and FIG. 2C shows a state in which chipping has occurred. As shown in FIG. 2A, when a foreign matter H1 is mixed in an individualized piece or on the base material film, the individualized piece is determined to be defective by appearance inspection if the foreign matter H1 is, for example, a metallic or non-metallic matter having a particle size larger than that of conductive particles. In addition, as shown in FIG. 2B, when a distortion H2 has occurred in an individualized piece, the individualized piece is determined to be defective upon appearance inspection if the distortion H2 has a width of, for example, ±50 μm or more. Furthermore, as shown in FIG. 2C, when a chipping H3 has occurred on the outer surface of an individualized piece, the individualized piece is determined to be defective upon appearance inspection if the chipping H3 is, for example, ±50 μm or larger.

The identification mark 30 can be applied using a laser marker, inkjet, punching, and the like, and among these, it is preferred to be laser-printed by a laser marker. When the identification mark 30 is applied using an inkjet, e.g., ink is scattered in the surrounding area, which may lead to misjudgment of defective individualized pieces or new defects due to staining. In addition, if defective individualized pieces are marked by punching without stopping the conveyance, the shape change caused by the punching holes may deteriorate the winding quality when winding the long film, in which the individualized pieces are arranged, onto a reel, and the punching marks may be transferred to the individualized pieces in the adjacent winding layer, and the punching process also requires the collection of waste material. In addition, the film vibration caused by punching adversely affects the focus of the inspection camera in the previous stage, making it difficult to apply a mark without stopping the conveyance. These concerns can be eliminated by using laser marking to provide the identification mark 30.

When conductive particles are contained, the width of the identification mark 30 is greater than or equal to the particle diameter of the conductive particles, preferably greater than 20 μm, more preferably greater than 50 μm, and still more preferably greater than 100 μm. This improves the identification ability of the identification mark 30.

The position of the identification mark 30 is not limited as long as the defective individualized pieces can be identified; for example, when an area of the base material film is provided at the edge of the long film in the width direction, the identification mark 30 may be printed only on the base material film at the edge of the defective individualized piece, only on the defective individualized piece, or on both the defective individualized piece and the base material film at the edge of the defective individualized piece. In addition, e.g., when an area of base material film is provided at the edge of a long film in the width direction, it may be printed only on the base material film at the edge of the non-defective individualized piece, or it may be printed on the base material film at the edge of the individualized piece positioned before a defective individualized piece.

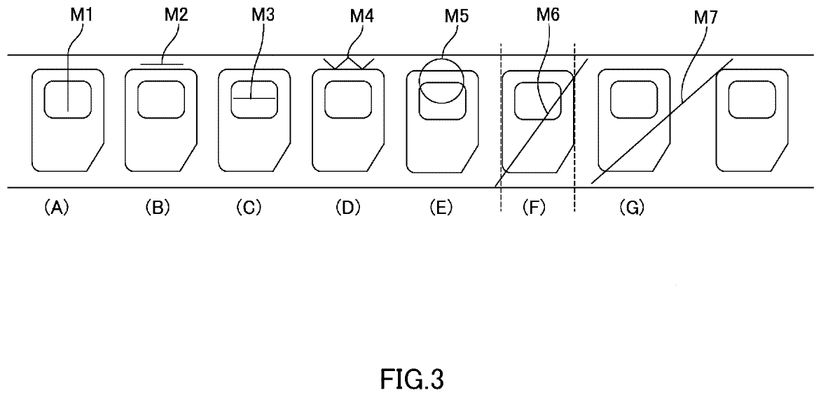

FIG. 3 illustrates examples of the identification mark. As shown in FIG. 3A, for example, an identification mark M1 may be a line in the width direction printed from the center of the window frame of the individualized piece to the edge area consisting of the base material film. As shown in FIG. 3B, for example, an identification mark M2 may be a line in the conveyance direction printed on the edge area consisting of the base material film. As shown in FIG. 3C, for example, an identification mark M3 may be a line in the conveyance direction printed within the window frame of the individualized pieces. As shown in FIG. 3D, for example, an identification mark M4 may be a zigzag line in the conveyance direction printed on the edge area consisting of the base material film. As shown in FIG. 3E, for example, an identification mark M5 may be a circle printed from the center of the window frame of the individualized piece to the edge area consisting of the base material film. As shown in FIG. 3F, for example, an identification mark M6 may be a diagonal line printed on the inside of both ends of the individualized pieces in the conveyance direction. As shown in FIG. 3G, for example, an identification mark M7 is not limited as long as it is not printed on adjacent individualized pieces and can identify the defective individualized piece.

According to such a long film, when using the individualized pieces, defective individualized pieces can be avoided by image recognition of the identification mark to ensure the performance of the individualized pieces of adhesive film. In addition, each individualized piece can be managed for safe use by the user, and the connection properties (conductivity, adhesive strength, insulation, and reliability, among others) of the product can ensured in a more stable manner.

### 2. Inspection Marking Device

The inspection marking device of this embodiment includes: a conveying unit that conveys a long film in a longitudinal direction in which individualized pieces of adhesive film are arranged in the longitudinal direction of a base material film; a detecting unit that detects each individualized pieces on the conveyed long film; an inspecting unit that inspects each individualized piece on the conveyed long film; a marking unit that applies an identification mark to a predetermined individualized piece of the conveyed long film or the base material film on which the individualized piece is arranged; and a control unit that acquires position information including the detected position of each individualized piece of long film in the longitudinal direction from the detecting unit, acquires inspection information of each individualized piece from the inspecting unit based on the position information of each individualized piece, and causes the marking unit to apply an identification mark based on the position information and inspection information of each individualized piece. This enables high-speed inspection of individualized pieces of adhesive film to improve productivity, and when the individualized pieces are used, defective individualized pieces can be avoided by image recognition of the identification mark.

It is also preferred that the control unit records the marking position of each individualized piece for the marking unit together with the detected position of each individualized piece in the position information, and the marking unit applies the identification mark based on the marking position of each individualized piece. This makes it easy to output a print trigger and stabilize the identification mark position even as the conveyance speed increases.

It is also preferred that the control unit records the inspection position of each individualized piece for the inspecting unit together with the detected position of each individualized piece in the position information, and the inspecting unit inspects each individualized piece on the conveyed long film based on the inspection position of each individualized piece. This makes it easy to output an imaging trigger and stabilize the inspection position of the individualized pieces even as the conveyance speed increases.

It is also preferable that the control unit controls the timing of the identification mark application in the marking unit based on the conveyance speed of the long film. This can, e.g., suppress misalignment of the print position during acceleration and deceleration.

The marking unit can use a laser marker, inkjet, punching, and the like, and among these, it is preferred to use a laser marker to apply identification marks. When the identification mark is applied using an inkjet, e.g., ink is scattered in the surrounding area, which may lead to misjudgment of defective individualized pieces or new defects due to staining. In addition, if defective individualized pieces are marked by punching without stopping the conveyance, the shape change caused by the punching holes may deteriorate the winding quality when winding the long film, in which the individualized pieces are arranged, onto a reel, and the punching marks may be transferred to the individualized pieces in the adjacent winding layer, and the punching process also requires the collection of waste material. In addition, the film vibration caused by punching adversely affects the focus of the inspection camera in the previous stage, which affects the conveyance speed and may adversely affect productivity. These concerns can be avoided by using laser marking as the marking unit.

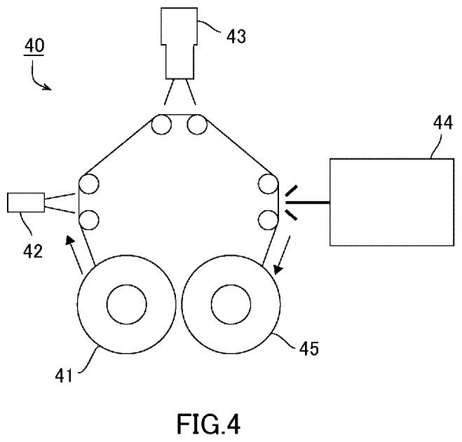

FIG. 4 illustrates an example configuration of an inspection marking device. As shown in FIG. 4, the inspection marking device 40 includes an unwinding mechanism 41, a detection sensor 42, an inspection camera 43, a laser marker 44, and a winding mechanism 45. The appearance inspection marking device also includes a control unit that controls the unwinding mechanism 41, the detection sensor 42, the inspection camera 43, the laser marker 44, and the winding mechanism 45. Here, the unwinding mechanism 41 and the winding mechanism 45 correspond to the above-mentioned conveying unit, the detection sensor 42 corresponds to the above-mentioned detecting unit, the inspection camera 43 corresponds to the above-mentioned inspecting unit, and the laser marker 44 corresponds to the above-mentioned marking unit.

Although not shown in the figure, the unwinding mechanism 41 is equipped with a supply reel to accommodate a long film, a supply motor that rotates and drives the supply reel so that the long film is unwound from the supply reel, and rollers that support the long film in a rolling contact state, among others, to unwind the long film from the supply reel and convey it in a longitudinal direction. Although not shown in the figure, the long film from the unwinding mechanism 41 to the winding mechanism 45 is subjected to a tensile force in the longitudinal direction of the long film, e.g., by the action of the rollers.

The detection sensor 42 includes a line sensor camera, an area line camera, or the like, to detect each individualized piece on the conveyed long film. For example, individualized pieces can be detected by capturing images of the conveyed long film in the width direction by using the line sensor camera and detecting the difference in reflected light between cases where there is an individualized piece on the base material film and cases where there is no individualized piece.

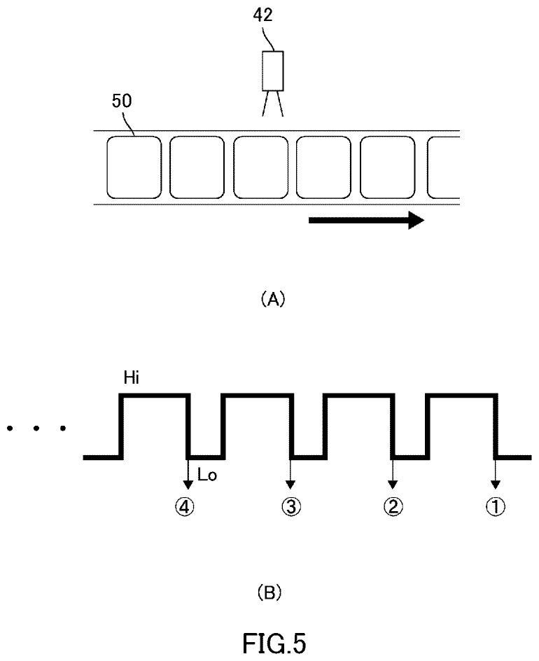

FIG. 5 illustrates an explanatory view of the operation of a detection sensor, wherein FIG. 5A shows the detection sensor that detects each individualized piece of long film conveyed, and FIG. 5B shows the detection signal of the individualized pieces detected by the detection sensor. As shown in FIGS. 5A and 5B, the detection sensor 42 outputs a detection signal as Hi when there is an individualized piece and Lo when there is no individualized piece on the conveyed long film, for example, and the control unit detects each individualized piece 50 when the detection signal changes from Lo to Hi.

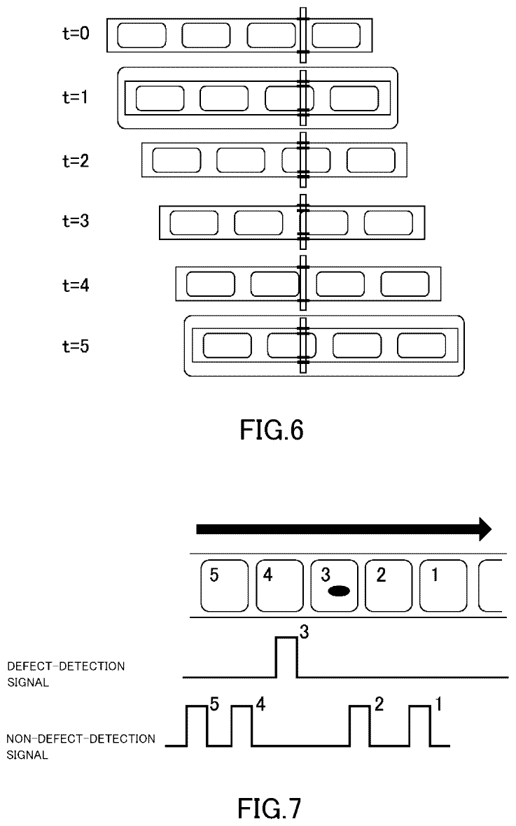

FIG. 6 is an explanatory view of the detection timing of the detection sensor. The detection sensor 42 takes images at the timing of t=0, t=1, t=2, t=3, t=4, and t=5, as shown in FIG. 6, and the control unit detects individualized pieces at the timing of t=1 and t=5 at which the detection signal changes from Lo to Hi.

As described below, when the imaging trigger of the inspection camera 43 and the print trigger of the laser marker 44 are set offset, the shorter imaging interval of the detection sensor 42 reduces the error in the detected position and improves the positioning accuracy of the imaging position of the inspection camera 43 and the laser marker 44. For this reason, the imaging interval of the detection sensor 42 is preferably 1 to 50 milliseconds, more preferably 1 to 10 milliseconds, and still more preferably 1 to 5 milliseconds.

The inspection camera 43 consists of, e.g., an area line camera to take images for appearance inspection of, e.g., debris remaining on the base material film, debris adhered to the individualized pieces, and individualized pieces turning up, and to record the results of appearance inspection in an individualized piece information memory of the control unit. It is preferred that the appearance inspection judges individualized pieces to be defective or non-defective and outputs defect-detection or non-defect-detection signals for the inspection judgment of a single individualized piece.

FIG. 7 illustrates an explanatory view of defect-detection and non-defect-detection signals in the inspection judgment. For example, as shown in FIG. 7, the appearance inspection outputs defect-detection and non-defect-detection signals for the inspection judgment of single individualized piece, and in this example, a defect-detection signal is output as Hi for the defective individualized piece with individualized piece number 3, and non-defect-detection signals are output as Hi for the non-defective individualized pieces with individualized piece numbers 1, 2, 4, and 5. This means that even if the defect judgment of the defective individualized piece with individualized piece number 3 is delayed and thus the defect-detection signal output is delayed, the result “defective” of individualized piece number 3 can be recorded in the memory as individualized piece information before the defective individualized piece with individualized piece number 3 reaches the print trigger of the laser marker 44, allowing more time for the judgment process.

The laser marker 44 irradiates a laser beam onto the object to change the state of the object surface by oxidation, peeling, coloration, and the like to apply an identification mark to at least one of the predetermined individualized piece or base material film without stopping the conveyance or having an excessive effect (such as vibration) on the conveyance. The laser marker 44 preferably employs a scanning method in which a single point of laser light is irradiated and the mark is printed as a single stroke. The laser used for the laser marker 44 may be selected according to the material of the base material film, adhesive film material of the individualized piece, and the like, and a fiber laser, UV laser, YVO₄ laser, CO₂ laser, YAG laser, and the like can be selected. The 44 laser marker is preferably equipped with a vacuum in the printing area to suppress the effect of dust generation.

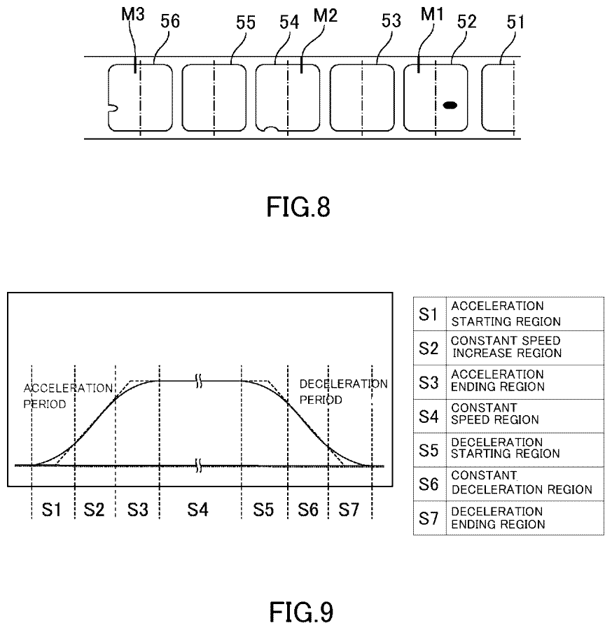

FIG. 8 illustrates an example of identification marks provided by a laser marker. As shown in FIG. 8, for example, the laser marker 44 applies the identification marks M1 to M3 to defective individualized pieces 52, 54, and 56, respectively, and does not apply the identification mark M to non-defective individualized pieces 51, 53, and 55. It is preferred that the identification marks are placed within the unit area, and it is more preferable that they are placed near the center of the unit area. This improves the identification ability of defective individualized pieces. In the example of applying the identification mark shown in FIG. 8, the marks are printed on both the defective individualized pieces and the base material film at the edge of the defective individualized pieces, but the present technology is not limited to this.

The winding mechanism 45 is equipped with a collection reel on which the long film is collected, a collection motor that rotates and drives the collection reel so that the long film is collected by the collection reel, and rollers that support the long film in a rolling contact state, among others, to wind the long film onto the collection reel after inspection and marking of the individualized pieces is completed.

The control unit consists of, e.g., a programmable logic controller (PLC) with a memory, and measures the conveyance distance traveled by the long film based on the length of the long film pulled out from the unwinding mechanism 41 or the length of the long film collected in the winding mechanism 45. The control unit also controls the long film supply and retrieval motors to run the long film at a predetermined conveyance speed. The conveyance speed of the long film is preferably 1 to 50 m/min, more preferably 5 to 50 m/min, and still more preferably 10 to 50 m/min.

The control unit acquires position information including the detected position of each individualized piece of the longitudinal direction of the long film from the detection sensor 12 and records the position information as individualized piece information in the memory. The control unit also acquires inspection information for each individualized piece from the inspection camera 43 based on the position information of each individualized piece and records the inspection information as individualized piece information in the memory. The control unit also causes the laser marker 44 to apply an identification mark based on the individualized piece information of each individualized piece. The control unit also controls the image timing of the inspection camera 43 and the printing timing of the laser marker 44 based on the individualized piece information.

Table 1 shows an example of the individualized piece information recorded in the memory. As shown in Table 1, the individualized piece information includes the individualized piece number (individualized piece No.), the measurement length for the individualized piece detected by the detection sensor 42 (presence/absence detection measurement length), the measurement length for the imaging trigger of the inspection camera 43 (camera trigger measurement length), the inspection result by the inspection judgment (inspection result), the measurement length for the print trigger of the laser marker 44 (laser measurement length).

TABLE 1

| | sensor | camera | | |
|---|---|---|---|---|
| | detection | trigger | | laser |
| piece | measurement | measurement | inspection | measurement |
| No. | length | length | result | length |
| 1 | 100.00 mm | 400.00 mm | non-defective | 700.00 mm |
| 2 | 120.12 mm | 420.12 mm | defective | 720.12 mm |
| 3 | 140.14 mm | 440.14 mm | non-defective | 740.14 mm |
| 4 | 160.16 mm | 460.16 mm | defective | 760.16 mm |
| . . . | . . . | . . . | . . . | . . . |

The control unit records the individualized piece number for each individualized piece detected by the detection sensor 42 and also records the measurement length for the individualized piece detection indicating the detected position of each individualized piece in the longitudinal direction of the long film in the individualized piece information. It is preferred that the control unit records, in the individualized piece information, the measurement length for the imaging trigger indicating the inspection position of each individualized piece in the inspection camera 43 along with the detected position of each individualized piece, and that the inspection camera 43 inspects each individualized piece on the conveyed long film based on the measurement length for the imaging trigger of each individualized piece. In other words, the control unit can easily output the imaging trigger of the inspection camera 13 by offsetting the preset distance from the detection sensor 42 to the inspection camera 43 (300.00 mm in the example of the individualized piece information shown in Table 1).

In addition, it is preferred that the control unit records, in the individualized piece information, the measurement length for the print trigger, which is the marking position of each individualized piece in the laser marker 44, along with the detected position of each individualized piece and that the laser marker 44 applies an identification mark based on the measurement length for the print trigger of each individualized piece. In other words, the control unit can easily output the print trigger of the laser marker 44 by offsetting the preset distance from the detection sensor 42 to the laser marker 44 (600.00 mm in the example of the individualized piece information shown in Table 1).

In addition, it is preferred that the control unit controls the timing of the application of the identification marker by the laser marker 44 based on the conveyance speed of the long film. For example, it is preferred that the control unit compensates the print trigger based on the area of the acceleration/deceleration waveform of the supply motor or the collection motor.

FIG. 9 illustrates an example of acceleration and deceleration waveforms of a long film supply motor or a collection motor. As shown in FIG. 9, for example, the acceleration-deceleration waveform of the supply motor or the collection motor is accelerated by acceleration control and decelerated by deceleration control. The acceleration/deceleration waveform can be divided into, e.g., seven speed regions of acceleration starting region S1, constant speed increase region S2, acceleration ending region S3, constant speed region S4, deceleration starting region S5, constant deceleration region S6, and deceleration ending region S7. The control unit monitors the speed regions of the supply motor or the collection motor and sets correction values for the print trigger corresponding to the speed regions S1 to S7, respectively, to suppress print misalignment during acceleration and deceleration, for example.

Next, an example of the operation of the inspection marking device shown in FIG. 4 is described. The detection sensor 42 detects individualized pieces of adhesive film being conveyed from the unwinding mechanism 41 and records the measurement length for the conveyance distance traveled by the long film in the memory as individualized piece information each time an individualized piece is detected. The control unit also offsets the preset distance from the detection sensor 42 to the inspection camera 43 (imaging trigger measurement length) and the preset distance from the detection sensor 42 to the laser marker 44 (print trigger measurement length) in the individualized piece information each time an individualized piece is detected.

When the individualized piece has traveled the measurement length for the imaging trigger, the control unit outputs a camera imaging trigger to the inspection camera 43 to perform a appearance inspection and adds the inspection result to the individualized piece information, thereby linking the individualized piece and the inspection result. When an individualized piece for which the inspection result indicates a defect has traveled the measurement length for the print trigger, the control unit outputs a print trigger to the laser marker 44 to print an identification mark on the defective individualized piece.

According to this inspection marking device, the individualized pieces of adhesive film can be inspected at high speed without stopping the conveyance, and an identification mark can be applied on at least one of the predetermined individualized piece or the base material film, thereby improving productivity.

### 3. Method for Manufacturing Long Film

The method for manufacturing a long film according to this embodiment includes: a preparing step of preparing a long film in which individualized pieces of adhesive film are arranged in the longitudinal direction of a base material film; a conveying step of conveying the long film in a longitudinal direction; a detecting step of detecting each individualized piece on the conveyed long film and acquiring position information including a detected position of each individualized piece of the long film in the longitudinal direction; an inspecting step of inspecting each individualized piece on the conveyed long film based on the position information of each individualized piece and acquiring inspection information of each individualized piece; and a marking step of applying an identification mark to at least one of a predetermined individualized piece of the conveyed long film or a base material film on which the predetermined individualized piece is arranged, based on the position information and the inspection information of each individualized piece. This enables high-speed inspection of individualized pieces of adhesive film to improve productivity.

Here, it is preferred that the detecting step records the marking position of each individualized piece for the marking step in the position information, and the identification mark is applied based on the marking position of each individualized piece in the marking step. This makes it easy to output a print trigger and stabilize the identification mark position even as the conveyance speed increases.

It is also preferred that the detecting step records the inspection position of each individualized piece for the inspecting step in the position information, and the inspecting step inspects each individualized piece on the conveyed long film based on the inspection position of each individualized piece. This makes it easy to output an imaging trigger and stabilize the inspection position of the individualized pieces even as the conveyance speed increases.

In the marking step, it is preferred to control the marking timing of the identification mark based on the conveyance speed of the long film. This can, e.g., suppress misalignment of the print position during acceleration and deceleration.

The marking step can use a laser marker, inkjet, punching, and the like, and among these, it is preferred to use a laser marker to apply identification marks. When the identification mark is applied using an inkjet, e.g., ink is scattered in the surrounding area, which may lead to misjudgment of defective individualized pieces or new defects due to staining. In addition, if defective individualized pieces are marked by punching without stopping the conveyance, the shape change caused by the punching holes may deteriorate the winding quality when winding the long film, in which the individualized pieces are arranged, onto a reel, and the punching marks may be transferred to the individualized pieces in the adjacent winding layer, and the punching process also requires the collection of waste material. In addition, the film vibration caused by punching adversely affects the focus of the inspection camera in the previous stage, making it difficult to apply a mark without stopping the conveyance. These concerns can be avoided by using laser marking as the marking unit.

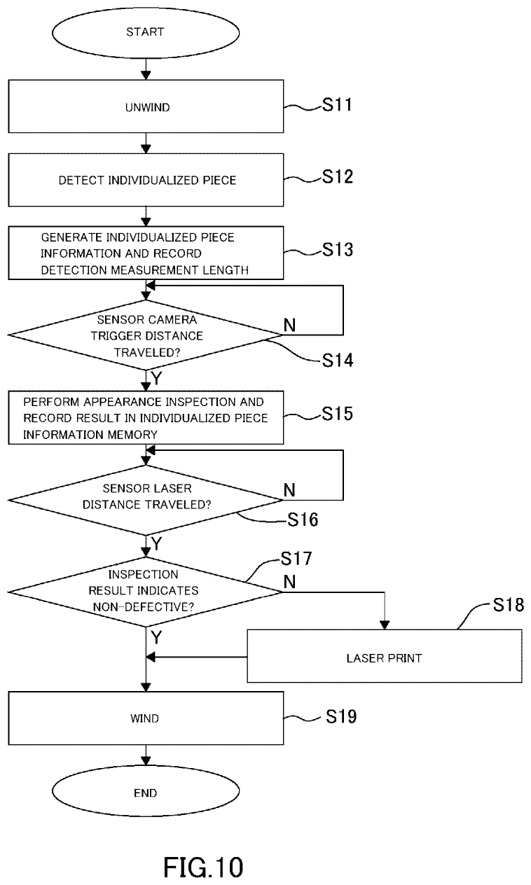

In the following, the preparing step (A), the conveying step (B), the detecting step (C), the inspecting step (D), and the marking step (E) are explained with reference to the inspection marking device shown in FIGS. 4 to 9 and the flowchart in FIG. 10 showing the inspection method for a long film.

### Preparing Step (A)

In the preparing step (A), a long film is prepared in which individualized pieces of adhesive film are arranged in the longitudinal direction of the base material film. The individualized pieces are preferably formed on the base material film by half-cut processing, screen printing, or inkjet printing. In the half-cut processing, only the adhesive film is cut without cutting the base material film using a cutting die, and unnecessary portions are removed by punching or other processes. In screen-printing, the adhesive is passed through the mesh of a screen mask under pressure with, e.g., a squeegee and printed (applied) on the base material film to produce individualized pieces of a predetermined thickness, e.g., according to the thickness of the screen mask. The screen mask is a plate made of a screen mesh woven with synthetic fibers such as polyester or stainless steel and various metal fibers. If the adhesive contains conductive or solder particles, the mesh should be larger than the maximum diameter of the conductive or solder particles. In inkjet printing, patterning is done directly from the data without the need for a plate, and the amount of application is controlled by the nozzle diameter, e.g., to produce individualized pieces of a predetermined thickness.

The individualized pieces may be composed of two or more layers, two or more laminated layers composed of layers containing conductive particles or solder particles and layers not containing conductive particles, two or more mutually laminated layers composed of layers containing conductive particles or solder particles, or two or more mutually laminated layers composed of layers not containing conductive particles or solder particles. When an individualized piece is composed of two or more layers, it is preferred to form the two or more layers by, e.g., coating or laminating before half-cutting. In addition, the individualized pieces may be made by screen printing and then laminated and formed. In addition, the individualized pieces may be made by nozzle-jet printing (inkjet printing), and then laminated and formed.

### Conveying Step (B)

In the next conveying step (B), the long film is conveyed in the longitudinal direction. In step S11, the control unit unwinds the long film in which the individualized pieces of adhesive film are arranged from the unwinding mechanism 41 and measures the conveyance distance indicating the position of the long film in the longitudinal direction.

### Detecting Step (C)

In the next detecting step (C), each individualized piece on the conveyed long film is detected, and position information including the detected position of each individualized piece in the longitudinal direction of the long film is acquired. First, in step S12, the control unit determines the presence or absence of individualized pieces on the base material film using the detection sensor 42 and acquires the measurement length for the conveyance distance, which is the position information of each individualized piece in the longitudinal direction of the long film.

Then, in step S13, the control unit records the individualized piece number (individualized piece No.) for each individualized piece detected by the detection sensor 42 and the measurement length for individualized piece detection (presence/absence detection measurement length) indicating the detected position of each individualized piece in the longitudinal direction of the long film in the individualized piece information, as shown in Table 1, for example.

The control unit also records, in the individualized piece information, e.g., the individualized piece information shown in Table 1, the measurement length for the imaging trigger indicating the inspection position of each individualized piece in the inspection camera 43 (camera trigger measurement length). That is, the control unit offsets the preset distance from the detection sensor 42 to the inspection camera 43 in the individualized piece information (300.00 mm in the example of the individualized piece information shown in Table 1).

In addition, the control unit records the measurement length for the print trigger (laser measurement length), which is the marking position of each individualized piece in the laser marker 14, in the individualized piece information as shown in Table 1. ? That is, the control unit offsets the preset distance from the detection sensor 42 to the laser marker 44 in the individualized piece information (600.00 mm in the example of the individualized piece information shown in Table 1).

### Inspecting Step (D)

In the next inspecting step (D), each individualized piece on the conveyed long film is inspected based on the position information of each individualized piece, and the inspection information of each individualized piece is acquired. First, in step S14, the control unit determines whether or not the measurement length for the imaging trigger indicating the inspection position of each individualized piece in the inspection camera 13 (camera trigger measurement length) has been traveled, and if it is determined that the measurement length for the imaging trigger has been traveled, the process proceeds to step S15.

Next, in step S15, the control unit performs a appearance inspection by capturing images of the individualized pieces with the inspection camera 13 based on the measurement length for the imaging trigger. It is preferred that the appearance inspection judges individualized pieces to be defective or non-defective and outputs defect-detection or non-defect-detection signals for the inspection judgment of a single individualized piece. The control unit records the inspection information of the judgment result, “non-defective” or “defective”, of the appearance inspection in the memory as the individualized piece information.

### Marking Step (E)

In the next marking step (E), based on the position information and the inspection information of each individualized piece, an identification mark is applied to at least one of a predetermined individualized piece of the conveyed long film or the base material film on which the predetermined individualized piece is arranged. First, in step S16, the control unit determines whether or not the measurement length for the print trigger indicating the marking position of each individualized piece in the laser marker 44 has been traveled, and if it is determined that the measurement length for the print trigger has been traveled, the process proceeds to step S17.

Next, in step S17, according to the inspection result, the control unit determines whether the predetermined individualized piece is non-defective or defective based on the individualized piece information recorded in the memory, and if the inspection result indicates “non-defective”, the process proceeds to step S19, and if the inspection result indicates “defective”, the process proceeds to step S18.

In step S18, the control unit causes the laser marker 44 to apply an identification mark to the defective individualized piece for which the inspection result of the individualized piece information indicates “defective”, and proceeds to step S19. In step S19, the control unit winds the long film onto the collection reel of the winding mechanism 45 after the inspection and marking of the individualized pieces are completed.

According to this method for manufacturing a long film, the individualized pieces of adhesive film can be inspected at high speed without stopping the conveyance, and an identification mark can be applied on at least one of the predetermined individualized piece or the base material film, thereby improving productivity.

### 4. Manufacturing Method of Connecting Structure

This method for manufacturing a connection structure includes: a pasting step of using a long film including a long base material film and individualized pieces of adhesive film arranged in the longitudinal direction of the base material film, wherein at least one of the predetermined individualized pieces or the base material film on which the predetermined individualized pieces are arranged is provided with an identification mark to enable a defective individualized piece to be identified and pasting only a non-defective individualized piece to the first or second electronic component having a terminal row based on the identification mark; and a connecting step of connecting the terminals of the first electronic component to the terminals of the second electronic component via the non-defective individualized piece.

### Pasting Step

In the pasting step, the above-mentioned long film is used to paste only the non-defective individualized pieces to the first or second electronic component having a terminal row based on the identification mark. For example, by using image recognition to identify and skip defective individualized pieces, a pasting device is used to press down on a non-defective individualized piece from the base material film side to paste the individualized piece to the mounting surface of the first or second electronic component on a stage. The long film from which the individualized pieces are detached may be wound away as the base material film only, and the defective individualized pieces may be wound away together with the base material film or pasted to a collection member so that the base material film only is wound away.

### Connecting Step

In the connecting step, the terminals of the first electronic component are connected to the terminals of the second electronic component via a non-defective individualized piece. For example, via a buffer material, the terminal rows of the first electronic component and the second electronic component are pressed together by a crimping tool. In addition, depending on the curing type of the adhesive film of the individualized pieces, heating, light irradiation, or the like is performed to cure the individualized pieces.

According to this method for manufacturing a connection structure, the performance of the individualized pieces of adhesive film used can be maintained, and excellent connection properties (continuity, adhesive strength, insulation, and reliability, among others) of the connection structure can be ensured.

### REFERENCE SIGNS LIST

10 long film, 11 base material film, 21 to 25 individualized pieces, 30 identification mark, 40 inspection marking device, 41 unwinding mechanism, 42 detection sensor, 43 inspection camera, 44 laser marker, 45 winding mechanism, 50 to 56 individualized pieces

1. A long film comprising a long base material film and individualized pieces of adhesive film arranged in the longitudinal direction of the base material film, wherein at least one of a predetermined individualized piece or the base material film on which the predetermined individualized pieces are arranged is provided with an identification mark to enable a defective individualized piece to be identified.

2. The long film according to claim 1, wherein an edge area comprising the base material film is provided at the edge of the long film in the width direction, and the edge area has the identification mark.

3. The long film according to claim 2, wherein the length of the edge area in the width direction is 100 μm or more.

4. The long film according to claim 1, wherein the individualized pieces have a window frame in which the base material film is exposed and the identification mark is put on the base material film of the window frame.

5. The long film according to claim 1, wherein the identification mark is laser-printed.

6. The long film according to claim 1, wherein the long film is wound on a reel.

7. A method for manufacturing a connection structure, comprising:
a pasting step of using a long film comprising a long base material film and individualized pieces of adhesive film arranged in the longitudinal direction of the base material film, wherein at least one of the predetermined individualized pieces or the base material film on which the predetermined individualized pieces are arranged is provided with an identification mark to enable a defective individualized piece to be identified and pasting only a non-defective individualized piece to the first or second electronic component having a terminal row based on the identification mark; and
a connecting step of connecting the terminals of the first electronic component to the terminals of the second electronic component via the non-defective individualized piece.

8. The long film according to claim 2, wherein the individualized pieces have a window frame in which the base material film is exposed and the identification mark is put on the base material film of the window frame.

9. The long film according to claim 3, wherein the individualized pieces have a window frame in which the base material film is exposed and the identification mark is put on the base material film of the window frame.

10. The method for manufacturing a connection structure according to claim 7, wherein an edge area comprising the base material film is provided at the edge of the long film in the width direction, and the edge area has the identification mark.

11. The method for manufacturing a connection structure according to claim 10, wherein the length of the edge area in the width direction is 100 μm or more.

12. The method for manufacturing a connection structure according to claim 7, wherein the individualized pieces have a window frame in which the base material film is exposed and the identification mark is put on the base material film of the window frame.

13. The method for manufacturing a long film, comprising:
a preparing step of preparing a long film in which individualized pieces of adhesive film are arranged in the longitudinal direction of a base material film; and
a marking step of inspecting each individualized pieces of the long film and applying an identification mark to enable a defective individualized piece to be identified at least one of a predetermined individualized piece of the long film or a base material film on which the predetermined individualized piece is arranged.
